(19) United States
(12) Patent Application Publication
(10) Pub. No.: US 2009/0140419 A1
(43) Pub. Date: Jun. 4, 2009

(54) EXTENDED PLATING TRACE IN FLIP CHIP SOLDER MASK WINDOW

(76) Inventors: Kenneth Rhyner, Rockwall, TX (US); Peter Harper, Lucas, TX (US)

Correspondence Address: TEXAS INSTRUMENTS INCORPORATED, P O BOX 655474, M/S 3999, DALLAS, TX, 75265, US

(21) Appl. No.: 11/947,310

(22) Filed: Nov. 29, 2007

(51) Int. Cl. H01L 23/48; H01L 21/44

(52) U.S. Cl. 257/737; 438/614; 257/E23.01; 257/E21.476

(57) ABSTRACT

A flip chip in accordance with an exemplary embodiment of the present invention has a ball grid array and a die disposed on the ball grid array, wherein the ball grid array includes conducting pads disposed under the die. Traces connecting conducting pads under the die are accessible to leads on the die by way of a solder mask window. These traces continue through the solder mask window and extend out to the border of the ball grid array and are used for both signaling purposes and electroplating purposes.

### BACKGROUND

Flip chip technology has become very popular in the semiconductor industry because of its size, performance, flexibility, reliability, and reduced cost. Flip chip assembly employs direct electrical connection of face-down integrated circuit (IC) chips onto a substrate, carrier, or circuit board, by means of conductive bumps on the chip bond pads. Instead of the older wire bonding technology, where the face-up chips were placed on substrates and connected to each bond pad via wires, the conductive bump is placed on the die surface and then the die is placed face-down connecting the bumps directly to the carrier.

Ball grid array technology has become a popular technique of connecting semiconductor chips with a circuit board. Ball grid array is typically characterized by the use of a substrate as chip carrier whose front side is used for mounting one or more chips and whose back side is provided with a grid array of solder balls, which are used to either mechanically bond or electrically couple to an external printed circuit board.

FIG. 1 illustrates a plan view of a conventional flip chip 100 including a carrier, in this case a ball grid array 102, and die 104. Die 104 is an IC chip having a plurality of conducting leads 106 spaced along its periphery. Each of plurality of conducting leads 106 is used to send signals from, and receive signals into, die 104. Ball grid array 102 includes a plurality of conducting pads 110 along its border. A plurality of traces 108 on ball grid array 102 connect a respective one of plurality of conducting leads 106 to one of plurality of conducting pads 110. Each of plurality of traces 108 additionally extends from a respective one of plurality of conducting pads 110 out toward electroplating bar 116 for electroplating purposes, which will be described in more detail below. Typically, a trace and conducting pad are formed of a conducting material, wherein each portion of the material is referred to as a separate item based on its respective function as discussed below.

With the above-described arrangement each of the plurality of leads 106 on die 104 is addressable, i.e., a signal may be sent thereto/received therefrom, by way of a respective conducting pad. Ball grid array 102 has 216 conducting pads thereon. This ball grid array is merely illustrative, wherein the number of pads is limited by the size of each pad, the size of the ball grid array, and the thickness of the traces.

FIG. 2 is an exploded view of portion 112 of conventional flip chip 100 of FIG. 1. As illustrated in the figure, die 104 is disposed on top of ball grid array 102. An insulating material is back-filled between die 104 and ball grid array 102, wherein the edge 222 of the insulating material is disposed on top of ball grid array 102. A solder mask window 202 is disposed on ball grid array 102 such that a portion 204 of solder mask window 202 is under die 104.

A trace 206 includes a signal trace portion 220 and an electroplating trace portion 210. Signal trace portion 220 extends from within solder mask window 202 to conducting pad 208. Further, electroplating trace portion 210 extends conducting pad 208 to the periphery of flip chip 100. Electroplating trace portion 210 is used for electroplating and will be described in detail below.

Trace 206 and conducting pad 208 are typically the same conducting material but are described as separate items for functional purposes. Trace 206 and conducting pad 208 (more specifically, plurality of traces 108 and plurality of conducting pads 110) are formed by conventional methods, non-limiting examples of which include depositing, plating and etching. Trace 206 and conducting pad 208 may typically include a first copper foil layer 207 that is commercially available and has a thickness in the range of approximately 12-15 μm. This type of commercially available copper foil layer may be too thin to adequately conduct signals and therefore may be further electroplated with a second layer of copper 209 that has a thickness in the range of approximately 10-12 μm.

A portion 212 of signal trace portion 220 is within solder mask window 202, and is therefore exposed. Portion 212 typically is coated with a non-oxidizing conductor, such as a nickel layer 213 of less than 3 μm, which is then coated with a gold layer 215 of less than 1 μm. Nickel layer 213 prevents oxidation of the exposed copper layer 209. Gold layer 215 increases conductivity between portion 212 and a conducting bump 214 disposed thereon. Conducting bump 214 is disposed on portion 212 to facilitate electrical connection with one of the plurality of conducting leads (not shown) of die 104. Conducting bump 214 is typically composed of a highly conductive material, non-limiting examples of which include Au and Au alloys. With this arrangement, conducting bump 214 electrically connects the conducting lead of die 104 to signal trace portion 220, and signal trace portion 220 electrically connects conducting bump 214 to conducting pad 208. As such, conducting pad 208 is electrically connected to the one of the plurality of conducting leads of die 104. With this arrangement, the conducting lead is addressable by way of the much larger conducting pad 208, which is disposed to cover a via 216.

FIG. 3 is a cross-sectional view of FIG. 2, along dashed line 218. As illustrated in the figure, ball grid array 102 includes a substrate 302, trace 206, conducting pad 208, nickel layer 213, gold layer 215, and solder mask 304. Trace 206 and conducting pad 208 each include copper foil layer 207 and copper layer 209. A conducting plug 306 within via 216 electrically connects conducting pad 208 to a solder ball 308. A lead (not shown) on die 104 is in electrical contact with conducting bump 214, which is in electrical contact with gold layer 215, which is in electrical contact with nickel layer 213, which is in electrical contact with signal trace portion 220, which is in electrical contact with conducting pad 208, which is in contact with conducting plug 306, which is in contact with solder ball 308. An insulating material 310 is back-filled between ball grid array 102 and die 104 to provide support for die 104. The height that edge 222 of insulating material 310 extends up to the side of die 104, the width that edge 222 extends out onto ball grid array 102 and the shape of edge 222 may be chosen to fit any number of design parameters, which are known to those of skill in the art. An over-mold epoxy-resin 314 disposed over die 104 and ball grid array 102 provided unitary packaging of die 104 and ball grid array 102.

When receiving a signal from the lead on die 104, the signal transmits through conducting bump 214, which then transmits through gold layer 215, which then transmits through nickel layer 213, which then transmits through signal trace portion 220, which then transmits through conducting pad 208, which then transmits through conducting plug 306, which then transmits through solder ball 308. When sending a signal to the lead, the signal transmits through solder ball 308, which then transmits through conducting plug 306, which then transmits through conducting pad 208, which then transmits through signal trace portion 220, which then transmits through nickel layer 213, which then transmits through gold layer 215, which then transmits through conducting bump 214, which then transmits to the lead.

The plurality of traces and conducting pads are typically referred to as a routing layer, because (as discussed above) this layer routs signals from solder ball 308 to the lead and vice versa. Trace 206 and conducting pad 208 are typically formed by known methods such as by depositing a thin copper foil on a substrate and then etching away unwanted portions. However, such methods leave trace 206 and conducting pad 208 with a less-than-desired thickness. Accordingly, copper layer 209 is typically disposed thereon. Copper layer 209 and conducting plug 306 are typically formed concurrently by an electroplating method.

In order to electroplate conducting plug 306 within via 216 and copper layer 209 onto layer 207, ball grid array 102 is immersed in a copper plating bath, along with a suitable counter-electrode (i.e., an anode). Electroplating trace portion 210 is connected to an electroplating bar 116 (illustrated in FIG. 1). An electrical potential is applied to trace 206 by way of electroplating bar 116. Current travels from electroplating bar 116 through trace 206, through the electroplating bath and to the submersed counter electrode. The top portion of layer 207 is then electroplated with copper layer 209, and the portion that is exposed through via 216 is electroplated with a layer of copper 316.

Solder mask 304 has many functions, such as preventing short-circuiting between conducting pad 208 and neighboring conducting pads, providing an insulation coating, preventing solder from flowing into other portions of substrate 302, and preventing unwanted oxidation of conducting pad 208 and trace 206. Solder mask 304 may be formed by any known method, non-limiting examples of which include curtain coating, screen curtain coating, dry film applying, dipping, and roller coating.

After the solder mask 304 has been deposited, a portion thereof is removed, by known methods, to create solder mask window 202. Solder mask window 202 enables eventual connection between die 104 and ball grid array 102.

Portion 212 of signal trace portion 220 is exposed through solder mask window 202 and is therefore subject to unwanted oxidation. Oxidation of portion 212 will decrease conductivity of signal trace portion 220 and therefore should be prevented.

An exemplary known method of preventing unwanted oxidation of portion 212 includes plating portion 212 by soldering. Any soldering material may be used as desired by the flip chip designer, non-liming examples of which include tin, gold, silver, lead, nickel and mixtures thereof.

Another exemplary known method of preventing unwanted oxidation of portion 212 includes electroplating portion 212. One method includes, prior to mounting die 104 on ball grid array 102, electroplating portion 212 of trace 206 with nickel layer 213 and gold layer 215, which are highly conductive and resistant to oxidation. Using nickel for layer 213 over the copper of copper layer 209 would prevent oxidation of the copper of copper layer 209. However, exposed nickel may form nickel oxide thus increasing resistance and reducing signal transfer between conducting bump 214 and trace 206. Therefore, gold of gold layer 215 disposed over nickel layer 213 improves electrical connection between conducting bump 214 and trace 206 and further prevents nonconductive nickel oxide from forming on nickel layer 213. Still further, having nickel layer 213 disposed between the gold of gold layer 215 and the copper of copper layer 209 prevents diffusion of the gold into the copper.

In order to electroplate nickel layer 213 onto portion 212 of trace 206, ball grid array 102 is immersed in a nickel plating bath, along with a suitable counter-electrode (i.e., an anode). Electroplating trace portion 210 is connected to electroplating bar 116, and an electrical potential is applied to trace 206. Current travels from electroplating bar 116 through trace 206, through portion 212 and layer 316, through the electroplating bath and to the submersed counter electrode. Portion 212 and layer 316 are then electroplated with nickel to form nickel layer 213 and nickel layer 318, respectively. This electroplating step is repeated with a gold plating bath to electroplate nickel layer 213 with gold layer 215, and to electroplate nickel layer 318 with gold layer 320. Portion 212 may then be referred to as a plated trace 312, whereas layers 316, 318 and 320 are conducting plug 306.

FIG. 4 is a cross-sectional view of conventional flip chip 100 of FIG. 1, as cut along line 114.

The number of addressable leads on die 104 are limited to the number of conducting pads 110 on ball grid array 102. A certain portion of ball grid array 102 must be reserved for traces 108. Of course a second routing layer may be added on top of solder mask 304, wherein another plurality of conducting pads and traces may be added to connect to additional addressable leads on die 104. However, such a plural layer package will have an increased fabrication time and cost.

What is needed is flip chip, which has an increased number of conducting pads that can address an increased number of die leads, and which uses non-functioning portions of the ball grid array without adding an additional routing layer.

### BRIEF SUMMARY

It is an object of the present invention to provide a flip chip, which has an increased number of conducting pads that can address an increased number of die leads, and which uses non-functioning portions of the ball grid array without adding an additional routing layer.

An exemplary embodiment of the present invention includes a device having a ball grid array and a die disposed on the ball grid array, wherein the ball grid array includes conducting pads disposed under the die.

An exemplary embodiment of the present invention includes a device having a substrate, a conducting pad, a trace and a mask layer. The substrate has a first side, a second side and a periphery. The substrate additionally has a via therein, that extends from the first side to the second side. The conducting pad is disposed on the first side at a position to cover the via. The trace is disposed on the first side and extends from the periphery to the conducting pad. The mask layer is disposed on the first side, the conducting pad and the trace. The mask layer includes a window disposed therein at a position between the conducting pad and the periphery. The window exposes a portion of the trace.

Another exemplary embodiment of the present invention includes a method of making a device. The method includes forming a substrate having a first side, a second side and a periphery; forming a via in the substrate, the via extending from the first side to the second side; disposing a conducting pad on the first side at a position to cover the via; disposing a trace on the first side and extending from the periphery to the conducting pad; disposing a mask layer on the first side, the conducting pad and the trace; and forming a window in the mask layer at a position between the conducting pad and the periphery, the window exposing a portion of the trace.

Additional objects, advantages and novel features of the invention are set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF SUMMARY OF THE DRAWINGS

The accompanying drawings, which are incorporated in and form a part of the specification, illustrate an exemplary embodiment of the present invention and, together with the description, serve to explain the principles of the invention. In the drawings:

FIG. 1 illustrates a plan view of a conventional flip chip;

FIG. 2 is an exploded view of a portion of the conventional flip chip of FIG. 1;

FIG. 3 is a cross-sectional view of a portion of FIG. 2;

FIG. 4 is a cross-sectional view of the conventional flip chip of FIG. 1;

FIG. 5 illustrates a plan view of an exemplary flip chip in accordance with the present invention;

FIG. 6 is an exploded view of a portion of the flip chip of FIG. 5;

FIG. 7 is a cross-sectional view of a portion of FIG. 6;

FIG. 8 is a cross-sectional view of flip chip 500 of FIG. 5;

FIGS. 9A-9L illustrate exemplary fabrication steps for the flip chip of FIG. 5;

FIG. 10 is an exemplary flowchart of the fabrication steps of FIGS. 9A-9L;

FIG. 11 is a cross-sectional view of a portion of another exemplary flip chip in accordance with the present invention; and

FIG. 12 is a cross-sectional view of the flip chip of FIG. 11.

### DETAILED DESCRIPTION

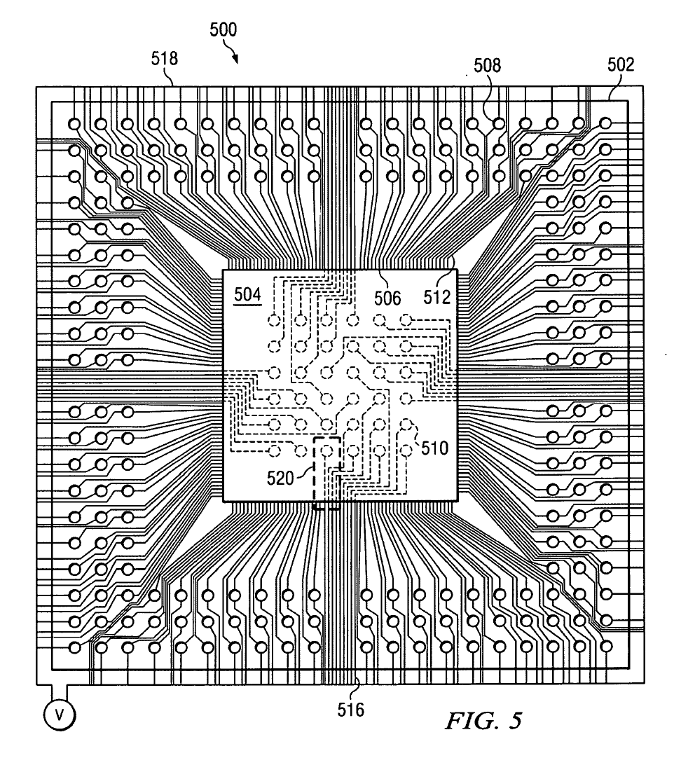

FIG. 5 illustrates a plan view of an exemplary flip chip 500 in accordance with an embodiment of the present invention. Flip chip 500 includes ball grid array 502 and die 504. Die 504 is an IC chip having a plurality of conducting leads 506 spaced along its periphery. Each of plurality of conducting leads 506 is used to send signals from, and receive signals into, die 504. Ball grid array 502 includes a plurality of conducting pads 508 along its border.

Further, ball grid array 502 includes a plurality of conducting pads 510 disposed under die 504. A plurality of traces 512 on ball grid array 502 connect a respective one of plurality of conducting leads 506 to one of plurality of conducting pads 508. Each side of ball grid array 502 is missing a set of conducting pads in areas 514. These areas are used for an additional plurality of traces 516 that connect to a respective one of plurality of conducting pads 510. Further, plurality of traces 516 that connect die leads to plurality of conducting pads 510 extend through the entire solder mask window and continue to the border of ball grid array for connection to electroplating bar 518. With this arrangement, plurality of traces 516 may be used for signal routing in addition to electroplating. This arrangement additionally allows conducting pads 510 disposed under die 504 to be used for signal routing, thus increasing the number of accessible die leads. As such, more leads on die 504 are addressable because signals may be sent thereto/received therefrom, by way of the group of conducting pads 508 and 510.

By sacrificing conducting pads on each side of ball grid array 502 in order to provide space 514 for the additional plurality of traces 516 that connect to the additional plurality of conducting pads 510 under die 504, ball grid array 502 has a total of 240 conducting pads thereon. As such, the exemplary flip chip in accordance with an embodiment of the present invention provides 24 more conducting pads for addressing die 504 than the conventional flip chip discussed above without the need for an additional routing layer. Of course, the ball grid array of FIG. 5 is merely illustrative, wherein the number of pads is limited by the size of each pad, the size of the ball grid array, and the thickness of the traces.

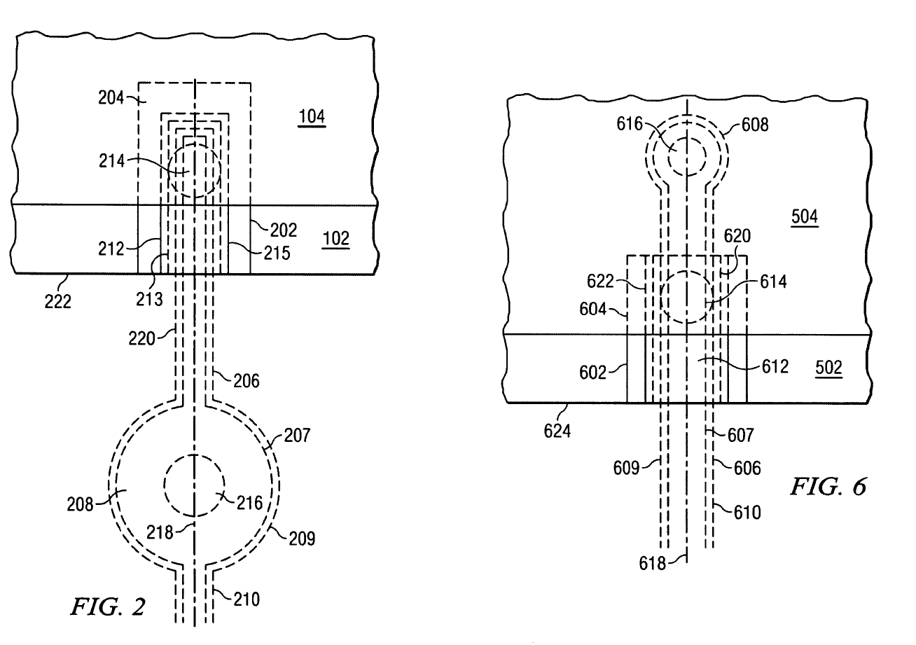

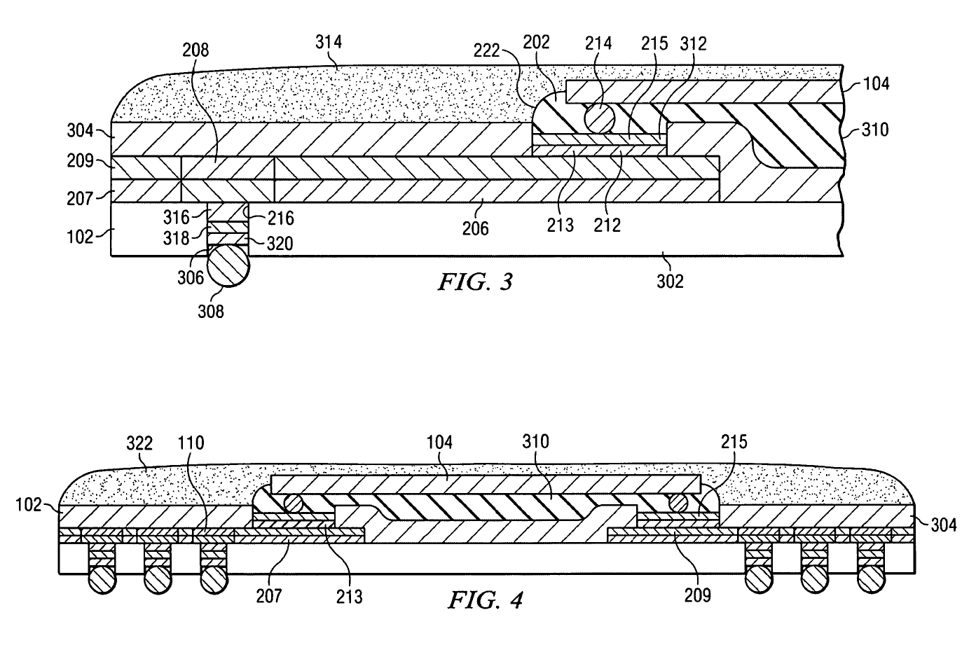

Plurality of conducting pads 508 may be conventionally electrically connected to conducting leads of die 504 by way of plurality of traces 512, as discussed above with respect to FIGS. 2 and 3.

Plurality of conducting pads 510 may be electrically connected to conducting leads of die 504 by way of plurality of traces 516 in accordance with an exemplary embodiment of the present invention, as will now be discussed with respect to FIGS. 6-10.

FIG. 6 is an exploded view of portion 520 of flip chip 500 of FIG. 5. As illustrated in the figure, die 504 is disposed on top of ball grid array 502. An insulating material is back-filled between die 504 and ball grid array 502, wherein the edge 624 of the insulating material is disposed on top of ball grid array 502. A solder mask window 602 is disposed on ball grid array 502 such that a portion 604 of solder mask window 602 is under die 504.

A trace 606 extends from conducting pad 608, through solder mask window 602 and beyond. Portion 610 of trace 606 is used for electroplating and will be described in detail below. In an exemplary embodiment, trace 606 and conducting pad 608 are the same conducting material but are described as separate items for functional purposes. In alternate embodiments, trace 606 and conducting pad 608 are different conducting materials.

Trace 606 and conducting pad 608 (more specifically, plurality of traces 516 and plurality of conducting pads 510) may be formed by conventional methods, non-limiting examples of which include depositing, plating and etching. In an exemplary embodiment, each of trace 606 and conducting pad 608 includes a first foil layer 607 of copper covered by a second electroplated copper layer 609.

A portion 612 of trace 606 is exposed in solder mask window 602. Portion 612, in this exemplary embodiment, is coated with a layer 620 of nickel and a layer 622 of gold. Other embodiments may include other non-oxidizing conductors.

Portion 612 of trace 606 has a conducting bump 614 disposed thereon to facilitate electrical connection with one of the plurality of conducting leads (not shown) of die 504. With this arrangement, conducting bump 614 electrically connects the conducting lead of die 504 to trace 606, and trace 606 electrically connects conducting bump 614 to conducting pad 608. As such, conducting pad 608 is electrically connected to the one of the plurality of conducting leads of die 504. With this arrangement, the conducting lead is addressable by way of the much larger conducting pad 608, which is disposed to cover a via 616.

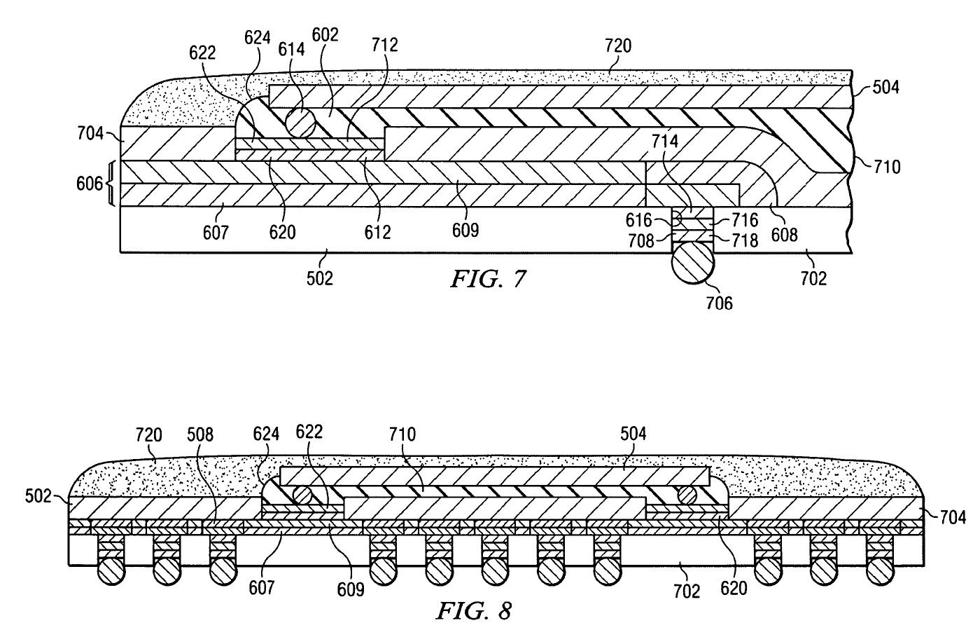

FIG. 7 is a cross-sectional view of FIG. 6, along dashed line 618. As illustrated in the figure, ball grid array 502 includes a substrate 702, a conducting plug 708, trace 606, conducting pad 608, nickel layer 620, gold layer 622, and a solder mask 704. Trace 606 and conducting pad 608 each include copper foil layer 607 and copper layer 609. Conducting plug 708 within via 616 electrically connects conducting pad 608 to a solder ball 706. A lead (not shown) on die 504 is in electrical contact with conducting bump 614, which is in electrical contact with gold layer 622, which is in electrical contact with nickel layer 620, which is in electrical contact with trace 606, which is in electrical contact with conducting pad 608, which is in contact with conducting plug 708, which is in contact with solder ball 706. An insulating material 710 may be back-filled between ball grid array 502 and die 504 to provide support for die 504. The height that edge 624 of insulating material 710 extends up to the side of die 504, the width that edge 624 extends out onto ball grid array 502 and the shape of edge 624 may be chosen to fit any number of design parameters, which are known to those of skill in the art.

When receiving a signal from the lead on die 504, the signal transmits through conducting bump 614, which then transmits through gold layer 622, which then transmits through nickel layer 620, which then transmits through trace 606, which then transmits through conducting pad 608, which then transmits through conducting plug 708, which then transmits through solder ball 706. When sending a signal to the lead, the signal transmits through solder ball 706, which then transmits through conducting plug 708, which then transmits through conducting pad 608, which then transmits through trace 606, which then transmits through nickel layer 620, which then transmits through gold layer 622, which then transmits through conducting bump 614, which then transmits to the lead.

Trace 606 and conducting pad 608 may be formed by known methods such as by depositing a thin copper foil on a substrate and then etching away unwanted portions to leave layer 607. However, such methods may leave trace 606 and conducting pad 608 with a less-than-desired thickness. Accordingly, layer 609 may be disposed onto layer 607 and may additionally comprise copper. Layer 609 and conducting plug 708 are may formed concurrently by any known method, a non-limiting example of which includes electroplating.

In one embodiment, in order to electroplate conducting plug 708 within via 616 and to electroplate layer 609 onto layer 607, ball grid array 502 is immersed in a copper plating bath, along with a suitable counter-electrode (i.e., an anode). Portion 610 is connected to an electroplating bar 518 (illustrated in FIG. 5). An electrical potential is applied to portion 610 by way of electroplating bar 518. Current travels from electroplating bar 518 through layer 607, through the electroplating bath and to the submersed counter electrode. The top portion of layer 607 is then electroplated with layer 609, and the portion of layer 607 that is exposed through via 616 is electroplated with a layer of copper 714.

Solder mask 704 may be formed by any known method, non-limiting examples of which include curtain coating, screen curtain coating, dry film applying, dipping, and roller coating. After the solder mask 704 has been deposited, a portion thereof is removed, by known methods, to create solder mask window 602. Solder mask window 602 enables eventual connection between die 504 and ball grid array 502.

A portion 612 of trace 606 is exposed through solder mask window 602 and is therefore subject to unwanted oxidation. Oxidation of portion 612 will decrease conductivity of trace 606 and therefore should be prevented.

An exemplary method of preventing unwanted oxidation of portion 612 includes plating portion 612 by soldering. Any soldering material may be used as desired by the flip chip designer, non-liming examples of which include tin, gold, silver, lead, nickel and mixtures thereof.

Another exemplary method of preventing unwanted oxidation of portion 612 includes electroplating portion 612. One method includes electroplating portion 612 with layers 620 and 622, which are highly conductive and resistant to oxidation. For example, using nickel for layer 620 over the copper of layer 609 would prevent oxidation of the copper of layer 609. However, exposed nickel may form nickel oxide thus increasing resistance and reducing signal transfer between conducting bump 614 and copper-coated trace 718. Therefore, gold of layer 622 disposed over the nickel of layer 620 improves electrical connection between conducting bump 614 and trace 606 and further prevents nonconductive nickel oxide from forming on layer 620. Still further, having the nickel of layer 620 disposed between the gold of layer 622 and the copper of layer 609 prevents diffusion of gold into copper.

In one exemplary method of electroplating layer 609 onto portion 612, ball grid array 502 is immersed in a metal plating bath, along with a suitable counter-electrode (i.e., an anode). Portion 610 is connected to an electroplating bar 518, and an electrical potential is applied to trace 606. Current travels from electroplating bar 518 through trace 606, through exposed portion 612 and layer 714 (in via 616), through the electroplating bath and to the submersed counter electrode. Exposed portion 612 and layer 714 are then electroplated with nickel to form layers 620 and 716, respectively. This electroplating step is repeated with a gold plating bath to electroplate layer 620 with gold to form layer 622, and to electroplate layer 716 with gold to form layer 718. Portion 612 may then be referred to as a plated trace 712. Layers 714, 716 and 718 may be referred to as conducting plug 708.

FIG. 8 is a cross-sectional view of flip chip 500 of FIG. 5, as cut along line 514.

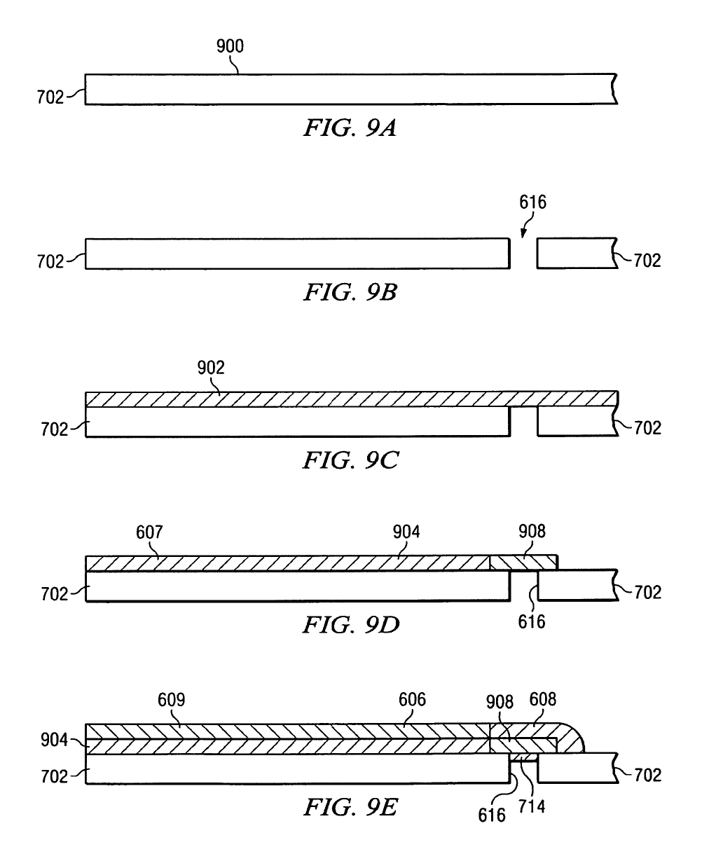

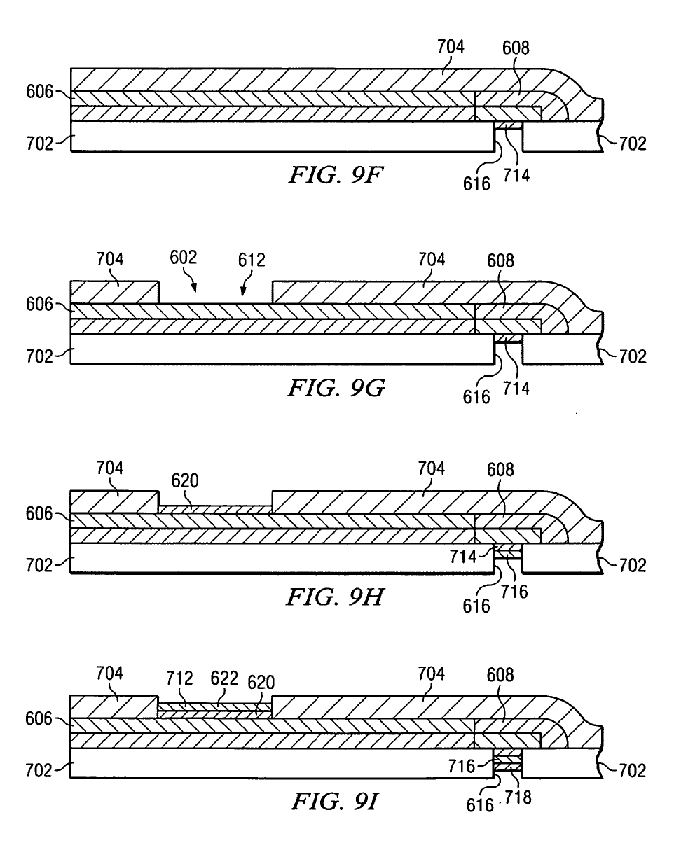

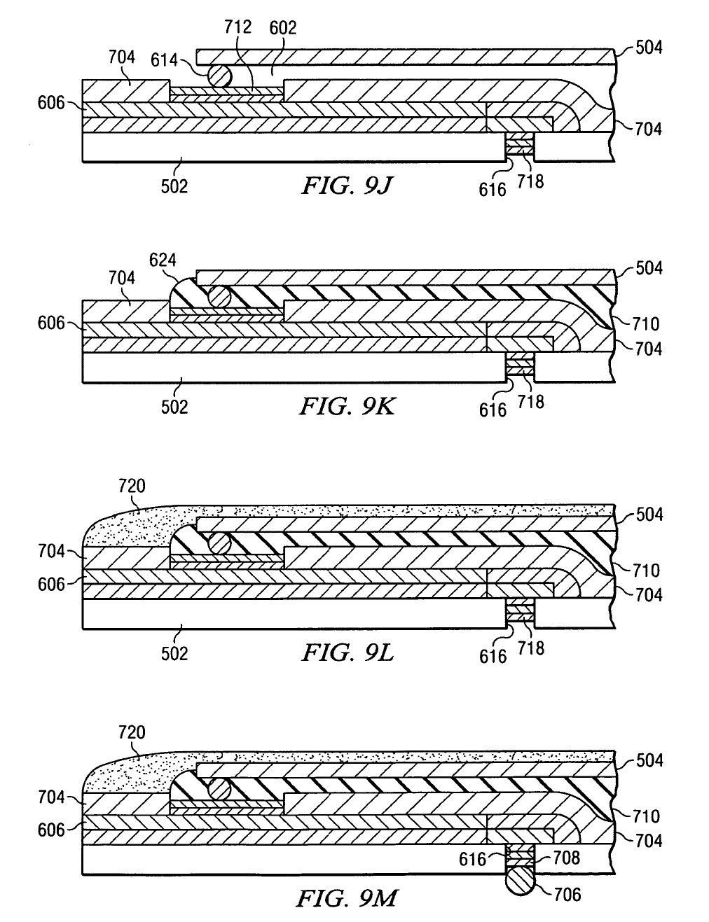

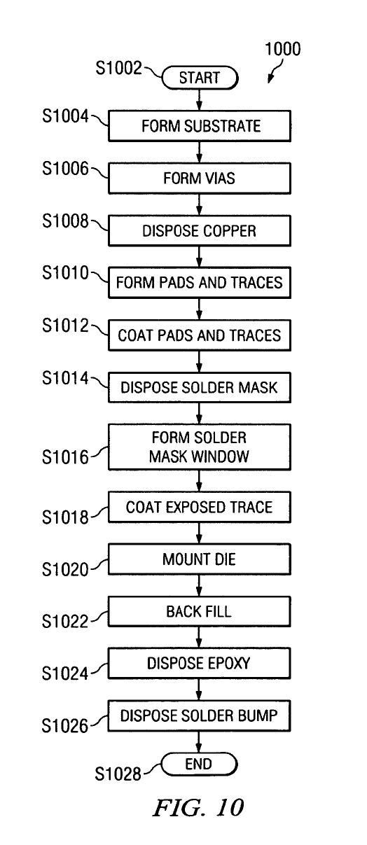

A method of manufacturing flip chip 500 of FIG. 5 in accordance with an exemplary embodiment of the present invention will now be described with reference to FIGS. 9A-9L and FIG. 10. FIGS. 9A-9L illustrate a cross sectional view of exemplary fabrication steps to form the device of FIG. 7, whereas FIG. 10 is a flowchart of the exemplary fabrication steps.

The method 1000 starts (S1002) and as illustrated in FIG. 9A, a substrate material layer 900 is fabricated by known methods to create substrate 702 (S1004).

Next, as illustrated in FIG. 9B, via 616 is formed in substrate 702 (S1006). Via 616 may be formed by any known method, non-limiting examples of which include etching, drilling and punching.

Next, as illustrated in FIG. 9C, a copper foil 902 is disposed on substrate 702 (S1008).

Next, as illustrated in FIG. 9D, copper foil 607 is etched via known methods to remove unwanted portions and thereby leave portion 904 and portion 908 (S1010). Portion 908 should be large enough to cover via 616 but small enough to prevent electrical contact between neighboring portions that cover neighboring vias.

In order to electroplate a metal onto exposed electrically conductive areas, substrate 702 may now be immersed in a copper plating bath, along with a suitable counter-electrode (i.e., an anode). An electrical potential is applied to each portion 904 (which corresponds to trace 516) by way of an electroplating bar 514. Current travels from bar 514 through each portion 904, through the electroplating bath and to the submersed counter electrode. Accordingly, copper is electroplated on the surface of portion 904 and the surface of portion 908 as copper layer 609, thus forming trace 606 and conducting pad 608. Further, copper is electroplated on the surface of portion 908 that is exposed through via 616 as layer 714 (S1012).

Next, as illustrated in FIG. 9F, a solder mask 704 is disposed by any known method to cover substrate 702, trace 606 and conducting pad 608 (S1014).

Next, as illustrated in FIG. 9G, solder mask window 602 is formed by known methods, a non-limiting example of which includes etching (S1016).

As illustrated in FIG. 9H, nickel layer 620 is disposed onto exposed portion 612 of trace 606 and nickel layer 716 is disposed onto layer 714 within via 616. In an exemplary embodiment, the nickel is electroplated in a manner similar to that described above with reference to FIG. 9E, the difference being the use of a nickel bath as opposed to a copper bath. In another exemplary embodiment, the nickel is soldered onto portion 612 and layer 714 by known methods.

Next, as illustrated in FIG. 9I, gold layer 622 is disposed onto nickel layer 620 and gold layer 718 is disposed onto nickel layer 716 within via 616. In an exemplary embodiment, the gold is electroplated in a manner similar to that described above with reference to FIG. 9H, the difference being the use of a gold bath as opposed to a nickel bath. In another exemplary embodiment, the gold is soldered onto layer 620 and layer 716 by known methods (S1018). At this point, substrate 702 may be disconnected from electroplating bar 514.

Next, as illustrated in FIG. 9J, die 504 may be attached to ball grid array 502, wherein each lead on die 504 has a respective conducting bump 614 disposed thereon (S1020). Conducting bump 614 contacts plated trace 712 within solder mask window 602.

As illustrated in FIG. 9K, insulating material 710 may be backfilled into the space between die 504 and ball grid array 502 (S1022) by any known method. Different known methods may provide different shapes to edge 624, e.g., concave, convex or straight. Further the amount of back-filled insulating material 710 that is used may determine the height and width of edge 624. Back-filled insulating material 710 fixes die 504 relative to ball grid array 502 and provides support for die 504.

As illustrated in FIG. 9L, an epoxy resin is disposed onto die 504 and ball grid array 502 for unitary packaging (S1024).

As illustrated in FIG. 9M, a solder bump 706 is then disposed by known methods into via 616 to contact conducting plug 708 (S1026). The fabrication is then complete (S1028).

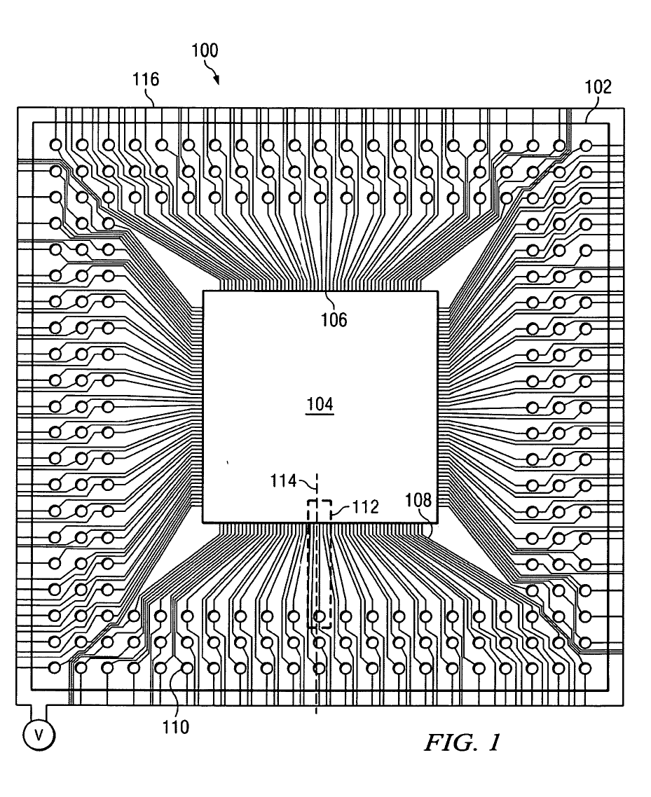

The above description with respect to FIGS. 6-10 highlight the differences between an exemplary embodiment of the present invention over the conventional flip chip design illustrated in FIG. 1. One specific difference deals with the relative position of the conducting pad, solder mask window and periphery of the ball grid array. In particular, as illustrated in FIG. 2, the prior art ball grid array is arranged such that the conducting pad 208 is disposed between the solder mask window 204 and the periphery of the ball grid array. On the contrary, as illustrated in FIG. 6, the ball grid array in accordance with an exemplary embodiment of the present invention includes at least one conducting pad 608 disposed under the die 504, such that the solder mask window 604 is disposed between the conducting pad 608 and the periphery of the ball grid array 502.

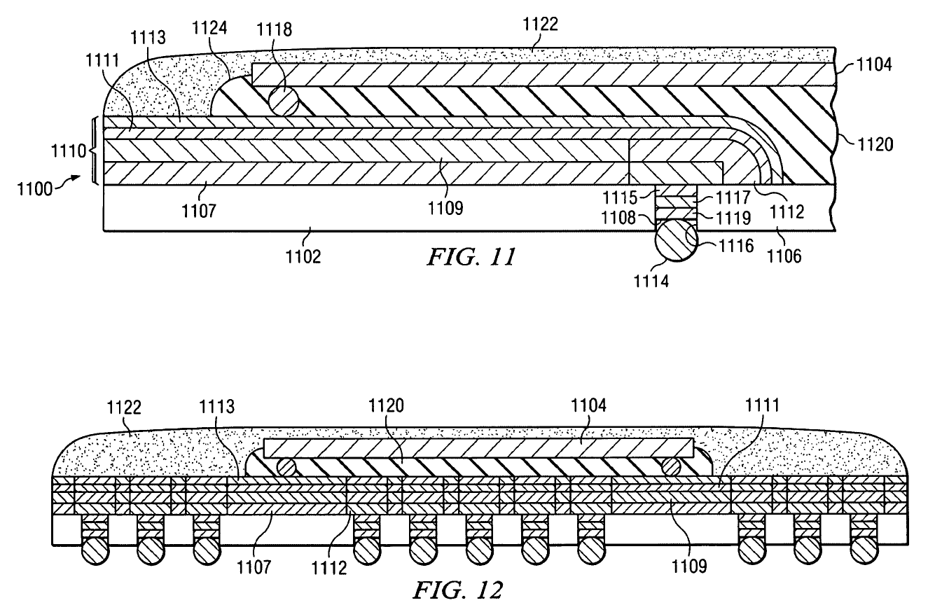

FIGS. 11 and 12 illustrate another exemplary embodiment of the present invention, wherein a gold conducting bump is disposed directly on a gold trace.

FIG. 11 is a cross-sectional view of a portion of device 1100 including a die 1104 and a ball grid array 1102. As illustrated in the figure, ball grid array 1102 includes a substrate 1106, a conducting plug 1108, a trace 1110, a conducting pad 1112 and a solder ball 1114.

Trace 1110 and conducting pad 1112 may be the same conducting material but are described as separate items for functional purposes. In this exemplary embodiment, trace 1110 and conducting pad 1112 are formed by conventional methods, non-limiting examples of which include depositing, plating and etching. In this exemplary embodiment, trace 1110 and conducting pad 1112 include a first copper foil layer 1107, a second layer of copper 1109, a layer of nickel 1111 and a layer of gold 1113. Further, conducting plug 1108 includes a layer of copper 1115, a layer of nickel 1117 and a layer of gold 1119.

Conducting plug 1108 within via 1116 electrically connects conducting pad 1112 to solder ball 1114. A lead (not shown) on die 1104 is in electrical contact with a conducting bump 1118, which is in electrical contact with trace 1110, which is in electrical contact with conducting pad 1112, which is in contact with conducting plug 1108, which is in contact with solder ball 1114. An insulating material 1120 may be back-filled between ball grid array 1102 and die 1104 to provide support for die 1104. The height that an edge 1124 of insulating material 1120 extends up to the side of die 1104, the width that edge 1124 extends out onto ball grid array 1102 and the shape of edge 1124 may be chosen to fit any number of design parameters, which are known to those of skill in the art. Further an epoxy resin 1122 may cover the top portion of ball grid array 1102 and die 1104 to create a unitary package.

In this embodiment, there is no solder mask, and therefore no solder mask window. In the embodiment illustrated in FIG. 7, gold is disposed solely in the area of the trace that lies within the solder mask window. Here, gold is disposed over the entire length of trace and conducting pad. Accordingly, the amount of gold required in this embodiment is much more than the amount of gold required in the embodiment illustrated in FIG. 7. However, in this embodiment, there is no solder mask, and therefore no solder mask window. As such, this embodiment requires at least two fewer fabrication steps than that of the embodiment illustrated in FIG. 7. As such, design constraints of fabrication time and cost must be considered when deciding which of the two embodiments to deploy. One of skill in the art would readily be able to determine which of the embodiments of FIG. 7 and FIG. 11 would be more appropriate for a particular application.

It should be noted that in accordance with the present invention, the portion of a ball grid array having conducting pads and corresponding traces that are not under the die may be fabricated with conventional techniques. It should be clear however, that in accordance with the exemplary embodiments of the present invention, the conventional fabrication steps will be modified to account for the novel design of conducting pads under the die. For example, returning to FIG. 5, plurality of traces 516 that connect die leads to plurality of conducting pads 510 extend through the entire solder mask window and continue to the border of ball grid array for connection to electroplating bar. With this arrangement, plurality of traces 516 may be used for signal routing in addition to electroplating. Further, this arrangement allows vias placed under die 504 to be used for signal routing, thus increasing the number of accessible die leads.

The foregoing description of various preferred embodiments of the invention have been presented for purposes of illustration and description. It is not intended to be exhaustive or to limit the invention to the precise forms disclosed, and obviously many modifications and variations are possible in light of the above teaching. The exemplary embodiments, as described above, were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed as new and desired to be protected by Letters Patent of the United States is:

1. A device comprising:
a substrate having a first side, a second side and a periphery, said substrate additionally having a via therein, said via extending from said first side to said second side;
a conducting pad disposed on said first side at a position to cover said via;
a trace disposed on said first side and extending from said periphery to said conducting pad; and
a mask layer disposed on said first side, said conducting pad and said trace,
wherein said mask layer includes a window disposed therein at a position between said conducting pad and said periphery, said window exposing a portion of said trace.

2. The device of claim 1, further comprising:
a conducting plug disposed within said via and being in contact with said conducting pad,
wherein said substrate has a first thickness from said first side to said second side, and
wherein said conducting plug has a second thickness that is less than said first thickness.

3. The device of claim 2, further comprising a conducting portion disposed within said via and in contact with said conducting plug, said conducting portion extending from said conducting plug to said second side.

4. The device of claim 3, further comprising:
a second substrate having a first side and a second side;
a conducting contact disposed on said first side of said second substrate; and
a conducting bump disposed on said conducting contact,
wherein said conducting bump is disposed on said exposed portion of said trace.

5. The device of claim 4, wherein said second substrate is separated from said substrate by a distance.

6. The device of claim 5, further comprising an insulating material disposed between said substrate and said second substrate.

7. The device of claim 1, wherein said conducting bump comprises one of gold and a gold alloy.

8. A device comprising:
a substrate having a first side, a second side and a periphery, said substrate additionally having a first via therein and a second via therein, each of said first via and said second via extending from said first side to said second side;
a first conducting pad disposed on said first side at a position to cover said first via;
a second conducting pad disposed on said first side at a position to cover said second via;
a first trace disposed on said first side and extending from said periphery to said first conducting pad;
a second trace disposed on said first side and extending from said periphery to beyond said second conducting pad; and
a mask layer disposed on said first side, said conducting pad, said first trace and said second trace,
wherein said mask layer includes a window disposed therein at a position between said first conducting pad and said periphery, said window exposing a portion of said first trace.

9. The device of claim 8, further comprising;
a conducting plug disposed within said first via and being in contact with said first conducting pad,
wherein said substrate has a first thickness from said first side to said second side, and
wherein said conducting plug has a second thickness that is less than said first thickness.

10. The device of claim 9, further comprising a conducting portion disposed within said first via and in contact with said conducting plug, said conducting portion extending from said conducting plug to said second side.

11. The device of claim 10, further comprising:
a second substrate having a first side and a second side;
a conducting contact disposed on said first side of said second substrate; and
a conducting bump disposed on said conducting contact,
wherein said conducting bump is disposed on said exposed portion of said first trace.

12. The device of claim 11, wherein said second substrate is separated from said substrate by a distance.

13. The device of claim 12, further comprising an insulating material disposed between said substrate and said second substrate.

14. The device of claim 8, wherein said conducting bump comprises one of Au and an Au alloy.

15. A device for receiving thereon a die having a conducting lead, a conducting bump and a periphery, the conducting lead being disposed at the periphery, the conducting bump being disposed on the conducting lead, said device comprising:
a substrate having a first side, a second side and a periphery, said substrate additionally having a via therein, said via extending from said first side to said second side;
a conducting pad disposed on said first side at a position to cover said via; and
a trace disposed on said first side, said trace extending from said periphery of said substrate to said conducting pad, and said trace having a first portion,
wherein said first portion of said trace is disposed at a position to contact the conducting bump upon receipt of the die, and
wherein said first portion is disposed between said conducting pad and said periphery of said substrate.

16. The device of claim 15, further comprising:
a conducting plug disposed within said via and being in contact with said conducting pad,
wherein said substrate has a first thickness from said first side to said second side, and
wherein said conducting plug has a second thickness that is less than said first thickness.

17. The device of claim 16, further comprising a conducting portion disposed within said via and in contact with said conducting plug, said conducting portion extending from said conducting plug to said second side.

18. A method of making a device, said method comprising:
forming a substrate having a first side, a second side and a periphery;
forming a via in the substrate, the via extending from the first side to the second side;
disposing a conducting pad on the first side at a position to cover the via;
disposing a trace on the first side and extending from the periphery to the conducting pad;
disposing a mask layer on the first side, the conducting pad and the trace; and
forming a window in the mask layer at a position between the conducting pad and the periphery to expose a portion of the trace.

19. The method of claim 18, further comprising
forming a conducting plug within the via,
wherein said forming a substrate comprises forming the substrate with a first thickness from the first side to the second side, and
wherein said forming a conducting plug comprises forming the conducting plug with a second thickness that is less than the first thickness.

20. The method of claim 19, further comprising forming a conducting portion within the via and in contact with the conducting plug, the conducting portion extending from the conducting plug to the second side.

21. The method of claim 20, further comprising:
forming a second substrate having a first side and a second side;
disposing a conducting contact on the first side of the second substrate;
disposing a conducting bump on the conducting contact; and
disposing the second substrate such that the conducting bump is disposed on the exposed portion of the trace.

22. The method of claim 21, wherein said disposing the second substrate comprises separating the second substrate from the substrate by a distance.

23. The method of claim 22, further comprising disposing an insulating material between the substrate and the second substrate.
